(19) United States
(12) Patent Application Publication
(10) Pub. No.: US 2012/0204420 A1
(43) Pub. Date: Aug. 16, 2012

(54) METHOD FOR MANUFACTURING WIRING BOARD

(75) Inventors: Toshiya ASANO, Ichinomiya-shi (JP); Nobuhiro ISHIKAWA, Kasugai-shi (JP); Tomonori SATOU, Komaki-shi (JP); Makoto WATANABE, Komaki-shi (JP); Kenichi YAMADA, Komaki-shi (JP)

(73) Assignee: NGK SPARK PLUG CO., LTD., Nagoya-shi (JP)

(21) Appl. No.: 13/371,947

(22) Filed: Feb. 13, 2012

(30) Foreign Application Priority Data
Feb. 14, 2011 (JP) 2011-29194

(51) Int. Cl. H05K 3/10

(52) U.S. Cl. 29/846

(57) ABSTRACT

A method for manufacturing a wiring board, which prevents electrostatic destruction generated in a mask pattern, by employing a structured exposure mask at a low cost is provided. The method can comprise the steps of forming a photosensitive resin layer on an insulating layer located underneath a predetermined conductor layer, forming a plating resist by exposing and developing the photosensitive resin layer with an exposure light while an exposure mask is disposed on a surface of the photosensitive resin layer, forming a metal plating layer that has a conductor pattern formed by applying a metal plating to an opening of the plating resist, and removing the plating resist. The exposure mask may have a plurality of graphic patterns, and each corner of the graphic patterns maybe chamfered by 50 micrometers or more so that electrostatic destruction due to electric discharge between the adjacent graphic patterns is prevented.

### CROSS REFERENCE TO RELATED APPLICATIONS

The present application claims priority from Japanese Patent Application No. 2011-29194, which was filed on Feb. 14, 2011, the disclosure of which is herein incorporated by reference in its entirety.

### BACKGROUND OF THE INVENTION

1. Field of the Invention

The present invention generally relates to a method for manufacturing a wiring board in which a conductor pattern of a predetermined conductor layer is formed with an exposure mask on a intermediate product that includes therein a product formation area for a plurality of products.

2. Description of Related Art

Conventional, known packages having thereon an element, such as a semiconductor chip, and are used for electrical connection between an external substrate and the element. A conventional wiring board structure may comprise a core material that is disposed in the center of the wiring board, and a wiring laminated body, in which a conductor layer and a insulating layer are alternately laminated, formed on top and bottom surfaces of the core material, respectively. When manufacturing the wiring board having such a structure, it is necessary to prepare an exposure mask having a mask pattern for forming a predetermined conductor pattern on each conductor layer. While the exposure mask is disposed so as to sandwich a dry film with a surface of the conductor layer, exposure and development processes are conducted by a conventionally known method. Thereafter, the dry film is removed, forming a predetermined conductor pattern. Generally, it is known that the exposure mask is likely to be charged with electricity during manufacturing processes. When the exposure mask is charged with electricity, electrostatic destruction tends to occur due to electric discharge between a plurality of patterns that are made of metal, such as chromium. Thus, there have been disclosed exposure masks capable of preventing such electrostatic destruction in, for example, Laid-Open Japanese Patent Application Nos. 2009-122295 and 2009-086384.

### BRIEF SUMMARY OF THE INVENTION

In a manufacturing process for a wiring board, a intermediate product used for obtaining a plurality of wiring boards has been generally employed, and the plurality of wiring boards are collectively processed in each process. An exposure mask corresponding to the intermediate product is the one that a metal mask pattern having a light blocking effect is drawn on a transparent glass substrate. The exposure mask is constituted by a plurality of conductor patterns in a lattice form. For example, when a solid conductor pattern is formed on a conductor layer of each wiring board, the mask pattern of an exposure mask is arranged so that rectangular patterns thereof adjoin each other. In such an arrangement, electrostatic destruction tends to occur near the corners of the adjacent patterns. Thus, a pattern defect is generated near the corners of the exposure mask due to an influence of electrostatic destruction, thereby reducing a production yield. If a distance between the adjacent patterns of the exposure mask is fully secured to prevent the electrostatic destruction, such arrangement limits an area for the conductor patterns, which is not desirable. On the other hand, masks disclosed in Japanese Patent Application Nos. 2009-122295 and 2009-086384 use a gray tone mask (gradation mask) having a complicated structure, which causes an increase in cost. In the manufacturing process of conventional wiring boards, techniques that prevent the electrostatic destruction generated near the corners of the adjacent patterns using a low cost exposure mask with a simple structure were not known.

Embodiments of the present invention have been conceived in order to solve the above problems, and an object of embodiments of the invention is to provide a method for manufacturing a wiring board capable of preventing electrostatic destruction generated near the corners of adjacent graphic patterns of an exposure mask, and that is capable of raising production yield of the wiring board using a simple structured exposure mask.

In order to solve the above-mentioned problems, there is provided a method for manufacturing a wiring board including a wiring laminated body having an insulating layer and a conductor layer that are alternatively laminated, and the wiring board being formed by an intermediate product having a product formation area for a plurality of products, the method comprising:

forming a photosensitive resin layer on an insulating layer located underneath of a predetermined conductor layer that is to be formed in the wiring laminated body;

forming a plating resist having an opening that corresponds to a mask pattern of an exposure mask by exposing and developing the photosensitive resin layer while the exposure mask is disposed on a surface of the photosensitive resin layer, the mask pattern having a conductive light-blocking film that blocks an exposure light irradiating to a conductor formation area of the predetermined conductor layer that is to be formed;

forming a metal plating layer that includes a conductor pattern corresponding to the mask pattern by applying a metal plating to the opening of the plating resist; and

removing the plating resist to form the predetermined conductor layer,

wherein each corner of a plurality of graphic patterns that constitute the conductive light-blocking film is chamfered by 50 micrometers or more.

According to the embodied method for manufacturing the wiring board of the invention, when the wiring boards are formed by the intermediate product, the exposure mask used for forming the plating resist in the predetermined conductor layer has the graphic patterns that constitute the conductive light-blocking film, and each corner of the graphic patterns is chamfered. Thus, in the mask patterns of the exposure mask, even though the graphic patterns are located adjacent to each other, any electrostatic destruction tending to be generated near the corners of the graphic patterns is suppressed, resulting in the prevention of most if not all pattern defects. Thus, the structure of the exposure mask is not necessarily complicated, and the conductor pattern formed in the predetermined conductor layer can maintain a high-density arrangement except that the corners thereof have certain limitations.

In the mask pattern of the exposure mask, each corner of the graphic patterns is chamfered by 50 micrometers or more. When the amount of chamfer on the corner is less than 50 micrometers, the electric discharge from the corners of the adjacent graphic patterns may not be suppressed, and electrostatic destruction may not be prevented. On the other hand, although an upper limit of chamfer of the corner is not defined, it is preferable that the amount of chamfer not be excessively increased because the area for forming the conductor pattern in the conductor layer is reduced.

Further, a chamfered corner can assume, for example, a circular arc shape. In this case, the amount of chamfer is represented as a radius of curvature of the rounded portion. However, the shape of the chamfered corner is not limited to the circular arc as long as electrostatic destruction is sufficiently prevented, and various shapes, such as a straight line and a curved line, can be adopted.

The embodied method for manufacturing a wiring board may be such that the intermediate product further includes a frame surrounding the product formation area, and the conductive light-blocking film further includes a pattern that blocks an exposure light irradiating to a conductor formation area of the frame. When the conductor pattern of the predetermined conductor layer is formed with the exposure mask having such a conductive light-blocking film, the conductor formation area of the frame surrounding the conductor formation area functions as a dummy conductor layer. Thus, it enhances uniformity of the conductor distribution between the center and the outside of the product formation area. In the mask pattern of the exposure mask, not only the corners of the graphic patterns corresponding to the product formation area but also the corners adjacent to the patterns corresponding to the frame need to be chamfered.

The embodied method for manufacturing a wiring board may also be such that the plurality of graphic patterns that constitute the conductive light-blocking film each correspond to one of the plurality of products in the product formation area. In other words, when an intermediate product includes, for example, “N” pieces of products in the product formation area, “N” pieces of graphic patterns may be formed in the mask pattern of the exposure mask so as to correspond to respective products. The embodied method may also be such that each corner of the plurality of graphic patters (e.g., a total of 4N corners) that constitute the conductive light-blocking film is chamfered in, for example, a circular arc shape with a radius of curvature of 50 micrometers or more. Such chamfering may be used at least for graphic patterns that have a rectangular shape.

In the wiring laminated body, the exposure mask of the invention may be applied to at least one predetermined conductor layer in the plurality of conductor layers, but may also be applied to all the conductor layers in the wiring laminated body. In other words, in certain embodiments the predetermined conductor layer may be all of the conductor layers included in the wiring laminated body.

The exposure mask of the invention is preferably used for a conductor layer having therein a conductor pattern that is prone to generate an electrostatic destruction. When a solid conductor pattern that is electrically connected to a power supply or a ground potential is formed in each conductor layer of adjacent products, the adjacent conductor patterns are normally located close to each other in order to extend an area for the conductor patterns. Thus, the superior and unexpected advantages of the exposure mask according to the invention are achievable.

As for a process relevant to the exposure mask in the method for manufacturing the wiring board of the invention, other processes may be added in addition to the resist removing step, the photosensitive resin layer formation step, the resist formation step and the plating step. For example, a metallic thin layer formation step may be added before the photosensitive resin layer formation step. Specifically, certain embodied methods may further comprise the steps of forming a metallic thin layer on the surface of the insulating layer located underneath the predetermined conductor layer that is to be formed before the photosensitive resin layer formation step, and/or etching a surface of the metal plating layer and a portion of the metallic thin layer where no metal plating layer is formed by a predetermined depth after the plating resist removing step.

According to embodiments of the present invention, each corner of the graphic patterns is chamfered by a predetermined amount when manufacturing the wiring board in which the insulating layer and the conductor layer are alternatively laminated. Thus, any electrostatic destruction caused by electric discharge from an acute corner of the graphic pattern can be prevented when the graphic patterns of the exposure mask are adjacent to each other. Accordingly, defective mask patterns due to electrostatic destruction of exposure masks can be reduced, and an improvement in production yield of wiring boards is achievable at a low cost using the simple structured exposure mask.

### BRIEF DESCRIPTION OF THE DRAWINGS

Illustrative aspects of the invention will be described in detail with reference to the following figures wherein:

FIG. 1 is a cross-sectioned structural view of a part of a wiring board according to an embodiment;

FIG. 2 is a schematic top view of a intermediate product for obtaining products of the wiring board according to the embodiment;

FIG. 3 is a schematic top view of an exposure mask used for forming a conductor pattern of a predetermined conductor layer included in the wiring board of the embodiment;

FIG. 4 is an enlarged view of partial area R1 of FIG. 3;

FIG. 5 is a first cross-sectional structural view showing a method for manufacturing the wiring board of the embodiment;

FIG. 6 is a second cross-sectional structural view showing the method for manufacturing the wiring board of the embodiment;

FIG. 7 is a third cross-sectional structural view showing the method for manufacturing the wiring board of the embodiment;

FIG. 8 is a fourth cross-sectional structural view showing the method for manufacturing the wiring board of the embodiment;

FIG. 9 is a fifth cross-sectional structural view showing the method for manufacturing the wiring board of the embodiment;

FIG. 10 is a sixth cross-sectional structural view showing the method for manufacturing the wiring board of the embodiment;

FIG. 11 is a seventh cross-sectional structural view showing the method for manufacturing the wiring board of the embodiment;

FIG. 12 is an eighth cross-sectional structural view showing the method for manufacturing the wiring board of the embodiment;

FIG. 13 is a ninth cross-sectional structural view showing the method for manufacturing the wiring board of the embodiment; and

FIG. 14 is a diagram showing the distribution of different exposure mask patterns used to test electrostatic discharge for the embodiment.

### DETAILED DESCRIPTION OF EXEMPLARY EMBODIMENTS OF THE INVENTION

Hereafter, an embodiment of the invention will be described with reference to the drawings. However, the embodiment described below is only an example and the invention is not limited to the contents of the embodiments. The following embodiments comprise a wiring board and a method for manufacturing the same that embody the technical scope and idea of the present invention.

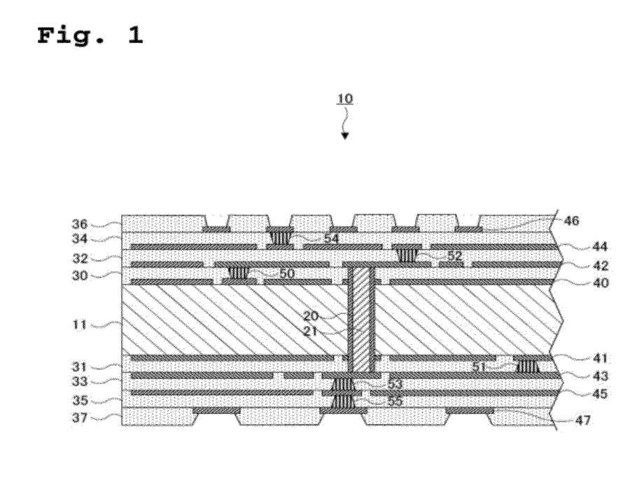

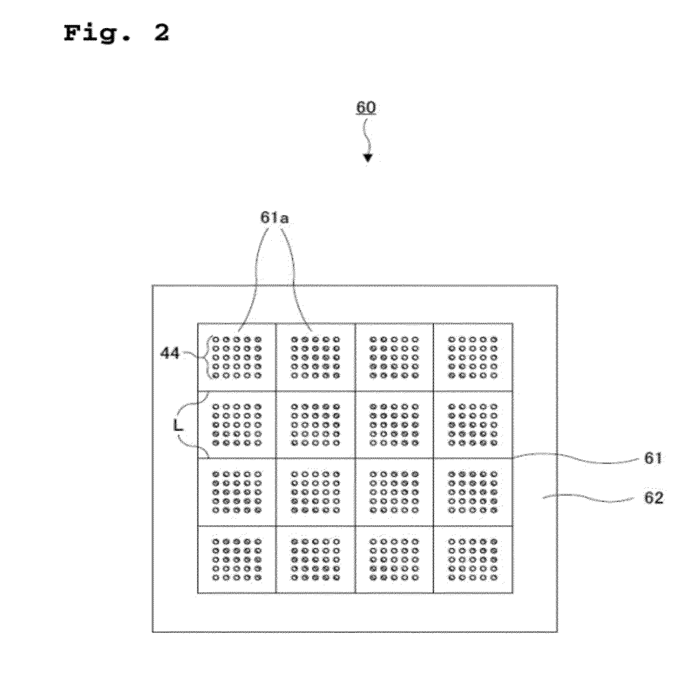

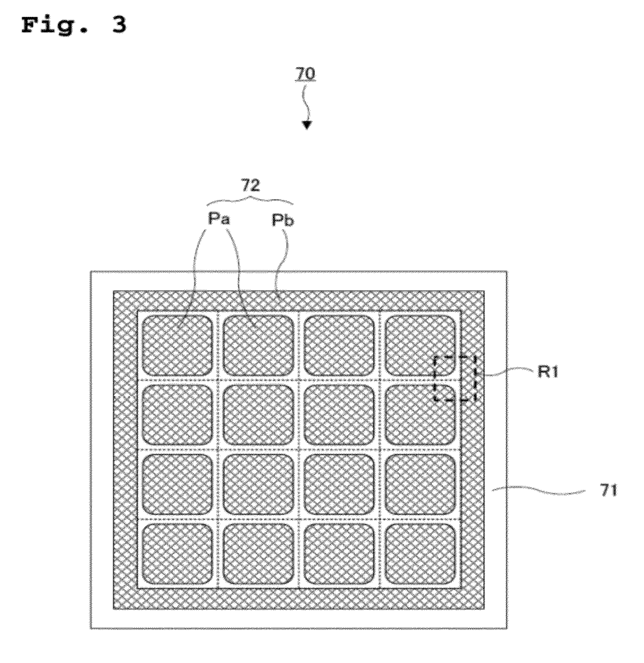

First, a configuration and a feature of the wiring board of the embodiment will be described with reference to FIGS. 1-4. FIG. 1 is a cross-sectioned structural view of a part of a wiring board 10 according to an embodiment. FIG. 2 is a schematic top view of a intermediate product 60 for obtaining products (e.g., piece parts) of the wiring board 10 according to the embodiment. FIG. 3 is a schematic top view of an exposure mask 70 used for forming a conductor pattern of a predetermined conductor layer in the wiring board 10. FIG. 4 is an enlarged view of a partial area R1 of FIG. 3.

The wiring board 10 shown in FIG. 1 includes: a plate-like core substrate 11 which supports the entire wiring board, and a wiring laminated body formed on each side of the core substrate 11 and having a structure in which an insulating layer and a conductor layer are alternatively laminated. The wiring board 10 of this embodiment is used as a package for establishing a connection between an external substrate and a component, such as a semiconductor chip, mounted thereon. The core substrate 11 is made of, for example, epoxy resin containing glass fiber. Further, the core substrate 11 in FIG. 1 may be, for example, a double-sided copper-clad laminate.

On the upper surface of the core substrate 11, a conductor layer 40, an insulating layer 30, a conductor layer 42, an insulating layer 32, a conductor layer 44, an insulating layer 34, a plurality of terminal pads 46 and a solder resist layer 36 are laminated in this order. Further, on the lower surface of the core substrate 11, a conductor layer 41, an insulating layer 31, a conductor layer 43, an insulating layer 33, a conductor layer 45, an insulating layer 35, a plurality of terminal pads 47 and a solder resist layer 37 are laminated in this order. Furthermore, a through hole conductor 20 is respectively formed in predetermined locations of the core substrate 11, the upper and lower conductor layers 40, 41 and the upper and lower insulating layers 30, 31 by extending therethrough in the laminating direction. The inside of the through hole conductor 20 is filled with a blockade body 21 made of, for example, glass epoxy. In addition, although only the single through hole conductor 20 is shown in FIG. 1, a plurality of through hole conductors 20 may be formed in each part of the core substrate 11.

The conductor layers 40 to 45 have conductor patterns used for supplying power and ground potential, and conductor patterns used for transmitting a signal. The conductor pattern of a predetermined conductor layer in the conductor layers 40 to 45 is formed with an exposure mask 70 (FIG. 3), which will be mentioned later, in the process of manufacturing the wiring board 10. Although the wiring board 10 according to the embodiment features a shape of a graphic pattern constituting the exposure mask 70 and a shape of the corresponding conductor pattern of the conductor layer, the detailed structure and the effect thereof will be described later. In FIG. 1, the conductor layers 42, 43 formed on both sides of the core substrate 11 are connected to upper and lower ends of the through hole conductor 20.

The insulating layers 30 to 35 and the solder resist layers 36 and 37 are made of, for example, an insulating material, such as epoxy resin. A via conductor 50 electrically connecting between the conductor layers 40, 42 in the laminating direction is formed at a predetermined location in the insulating layer 30. Further, a via conductor 52 electrically connecting between the conductor layers 42, 44 in the laminating direction is formed at a predetermined location in the insulating layer 32. Furthermore, a via conductor 54 electrically connecting between the conductor layers 44 and the terminal pad 46 in the laminating direction is formed at a predetermined location in the insulating layer 34. Similarly, via conductors 51, 53, 55 corresponding to the via conductors 50, 52, 54 are formed in the insulating layers 31, 33, 35, respectively. In addition, although FIG. 1 shows the single via conductor 50 to 55 in each insulating layer, the number of via conductors in each insulating layer is not limited, and a plurality of via conductors may be formed therein. Moreover, a plurality of terminal pads 46 are formed on a surface of the insulating layer 34 and are exposed from corresponding openings of the solder resist layer 36. On the other hand, a plurality of terminal pads 47 having a relatively large size are formed on a surface of the insulating layer 35 and are exposed from corresponding openings of the solder resist layer 37.

In FIG. 1, for example, when a semiconductor chip is connected to an external substrate through the wiring board 10, the plurality of upper terminal pads 46 may be connected to a plurality of pads of the semiconductor chip, and the plurality of lower terminal pads 47 may be connected to the external substrate through a plurality of solder balls. In this case, in the cross-sectional structure of FIG. 1, the electrical connection between the semiconductor chip and the external substrate can be established through the plurality of terminal pads 46, the via conductor 54, the conductor layer 44, the via conductor 52, the conductor layer 42, the through-hole conductor 20, the conductor layer 43, the via conductor 53, the conductor layer 45, the via conductor 55, and the plurality of terminal pads 47.

Next, as shown in FIG. 2, the intermediate product 60 of this embodiment assumes a rectangular planar shape. The intermediate product 60 is divided into a rectangular product formation area 61 located in the center thereof and a frame 62 surrounding the product formation area 61. Further, the product formation area 61 is further divided into a plurality of unit areas 61a that serve as single products (e.g., wiring boards 10). FIG. 2 shows a top view of the intermediate product 60 where the plurality of terminal pads 47 are arranged in each unit area 61a. Although the size of each unit area 61a can vary, for example, the unit area 61a may assume a rectangular form having a side length of between 45 to 60 mm. In the process of manufacturing the wiring board 10, for example, the adjacent unit areas 61a are divided along a boundary line L so that the plurality of wiring boards 10 may be formed. In FIG. 2, a total of 16 wiring boards 10 can be obtained from the product formation area 61 where 16 unit areas 61a, arranged in a 4×4 pattern, are formed. In addition, the intermediate product 60 of FIG. 2 is only an example and the number of the unit areas 61a formed in the intermediate product 60 is not limited. On the other hand, the frame 62 has solid conductor patterns in an area surrounding the conductor layers 40 to 45 in order to equalize the conductor density between the product formation area 61 and the frame 62.

On the other hand, the exposure mask 70 used in the process of manufacturing the wiring board 10 of the embodiment has a rectangular planar shape similar to the shape of the intermediate product 60, as shown in FIG. 3. The exposure mask 70 includes a transparent glass substrate 71 and a mask pattern 72 where a conductive light-blocking film having a plurality of graphic patterns is formed on a surface of the glass substrate 71. The mask pattern 72 is made of a metal, such as chromium, and is divided into a plurality of product conductor patterns Pa corresponding to the predetermined conductor layer of each unit area 61a of the intermediate product 60 and a frame conductor pattern Pb corresponding to the frame 62 of the intermediate product 60.

In FIG. 3, each product conductor pattern Pa has a structure including the via conductors 50 to 55 and those surroundings areas. In FIG. 3, for the purpose of simplification, each product conductor pattern Pa is presented as a solid conductor pattern. Thereby, for example, the solid conductor pattern connected to power supply or ground potential can be formed in the predetermined conductor layer of the unit area 61a of FIG. 2 corresponding to the product conductor pattern Pa. In addition, although any signal wiring may be partially formed in the predetermined conductor layer of the unit area 61a, the effect of the present invention can be enhanced when the area of the graphic pattern constituting each product conductor pattern Pa of the exposure mask 70 is wide and an outer circumference of the graphic pattern is widened.

FIG. 4 shows a partial area R1 of FIG. 3 where a pair of adjacent product conductor patterns Pa and the frame conductor pattern Pb formed in the vicinity of the product conductor pattern Pa are formed. The adjacent product conductor patterns Pa are arranged so as to have a space G1 therebetween, and the product conductor pattern Pa and the frame conductor pattern Pb are arranged so as to have a space G2 therebetween. As shown in FIG. 4, in each product conductor pattern Pa of this embodiment, a chamfered portion Ra is formed in each corner of the rectangular graphic pattern. When the mask pattern 72 is used in the manufacturing process, electrostatic destruction tends to be generated due to a discharge from acute corners of the adjacent metal graphic patterns. Thus, in order to prevent this electrostatic destruction, the acute corners are chamfered.

The chamfered portion Ra of the product conductor pattern Pa is rounded, assuming, for example, a circular arc shape and preferably has a radius of curvature (e.g., an amount of chamfer) of 50 micrometers or more. When the radius of curvature of chamfered portion Ra is too small, the effect of preventing electrostatic destruction will be insufficient. However, when the radius of curvature of chamfered portion Ra is extremely large, an area near the corner of the product conductor pattern Pa is reduced, which restricts the formation of a conductor pattern in a predetermined conductor layer. In addition, although the exemplary shape of the chamfered portion Ra is shown in FIG. 4, it is not limited to that shape. As long as there are no acute corners in the product conductor pattern Pa, any shape is adaptable, such as a combination of various curves and straight lines.

Although the exposure mask 70 having the above-described structure may be applied to one, a portion, or all of the conductor layers 40-45 of the wiring boards 10 of FIG. 1, it may be applied to only a single conductor layer of the conductor layers 40-45. That is, the exposure mask 70 is preferably used for any of the conductor layers 40-45 which have a high-density solid conductor pattern. However, the exposure mask 70 is not necessarily used on a conductor layer whose conductor pattern has low density near the outer circumference thereof and has a low possibility to cause electrostatic destruction. Thus, the present invention is especially applicable in cases where the exposure mask 70 is used on at least a single predetermined conductor layer in the process of manufacturing the wiring board 10.

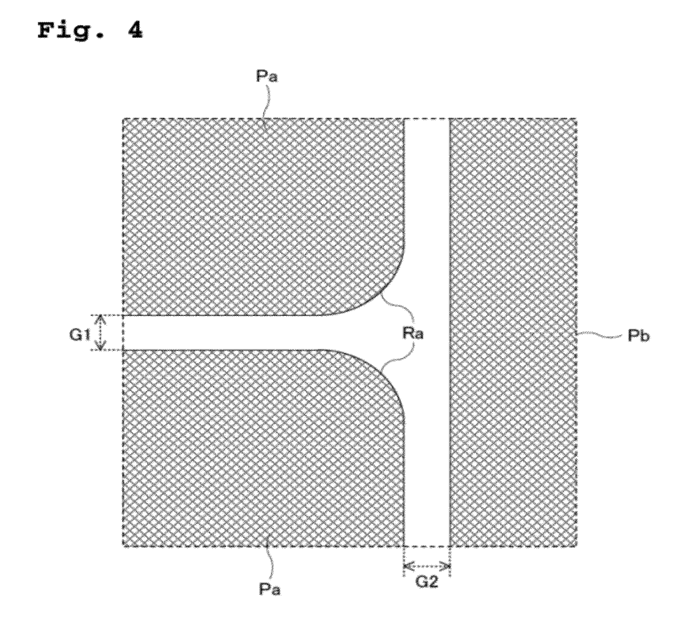

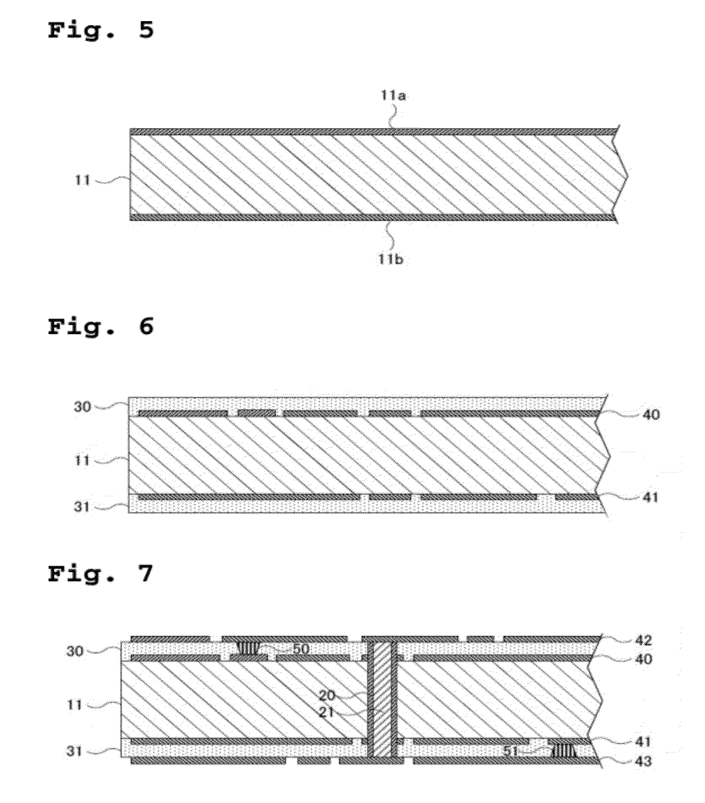

Next, a method for manufacturing the wiring board 10 of the embodiment will be described with reference to FIGS. 5 to 13. In addition, the following description assumes that a conductor pattern is formed on each conductor layer 44, 45 as the predetermined conductor layer of the wiring board 10 in FIG. 1 using the exposure mask 70 of FIG. 3.

First, as shown in FIG. 5, the plate-like core substrate 11 is prepared. The core substrate 11 is made of resin being rigid enough to support the wiring board 10, and copper foils 11a and 11b are laminated on both surfaces of the core substrate 11. As mentioned above, since the intermediate product 60 includes the plurality of wiring boards 10, the core substrate 11, for example, is an about 300 mm planar square. In addition, FIGS. 5 to 13 do not show the entire structure of the intermediate product 60, but show a partial cross-sectional structure of the single wiring board 10 (the same region as in FIG. 1), for the purpose of simplification.

As shown in FIG. 6, the conductor layers 40, 41 are formed on the copper foils 11a, 11b of the core substrate 11, respectively, by a known subtractive process. Then, a film-like insulating resin material containing epoxy resin as a principal component is laminated and cured on each surface of the conductor layers 40, 41 so as to form the insulating layers 30, 31.

Next, as shown in FIG. 7, a cylindrical through-hole extending through the core substrate 11 and the insulating layers 30, 31 is formed in a position where the through hole conductor 20 is supposed to be formed by a punching process using a drill machine. Thereafter, the through hole conductor 20 is formed by applying electroless copper plating and electrolytic copper plating to the through-hole. Then, a paste containing epoxy resin as a principal component is filled in the through hole conductor 20 and hardened so that the blockade body 21 is formed. Further, via holes are formed in predetermined positions of the insulating layers 30, 31 by a laser processing and thereafter they are subjected to a desmear treatment to form the via conductors 50, 51 in the via holes. On the other hand, copper plating layers are formed on the surfaces of the insulating layers 30, 31, respectively, through electroless copper plating, and the conductor layers 42, 43 are patterned thereon through, for example, a known subtractive process.

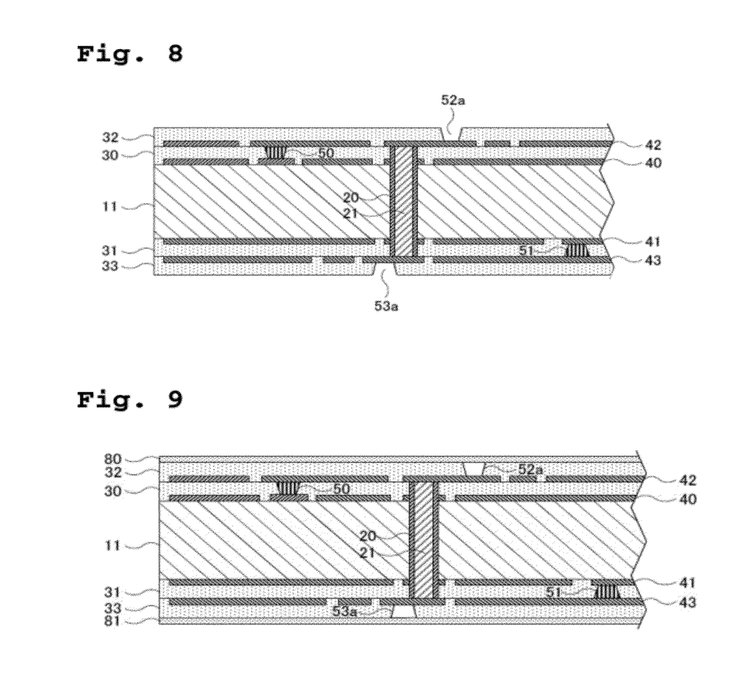

As shown in FIG. 8, a film-like insulating resin material made of epoxy resin as a principal component is laminated and cured on each surface of the conductor layers 42 and 43 to thereby form the insulating layers 32, 33. Thereafter, via holes 52a and 53a serving as the via conductors 52, 53 are formed in predetermined positions of the insulating layers 32, 33 by laser processing.

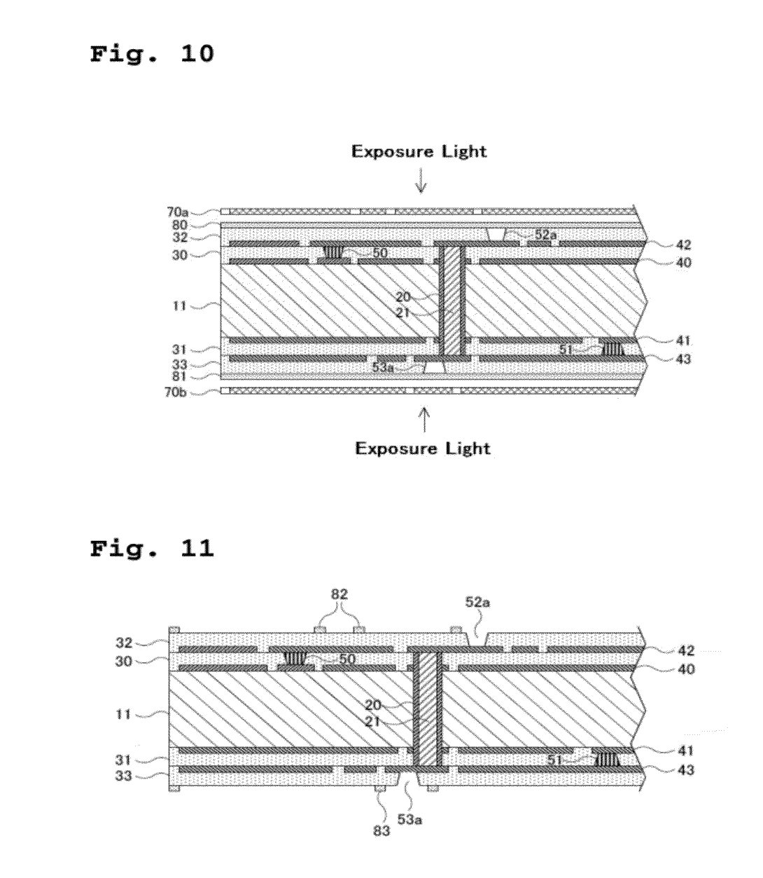

As shown in FIG. 9, a copper thin layer (not illustrated) is formed on each surface of the conductor layers 42, 43 through electroless copper plating (metallic thin layer formation process), and thereafter dry films 80 and 81 are covered thereon (photosensitive resin layer formation process). These dry films 80, 81 are photosensitive resin layers made of epoxy resin or the like. In this state, as shown in FIG. 10, exposure masks 70a and 70b having the structure of FIG. 3 are disposed on the dry films 80, 81, respectively, so that exposure light, such as ultraviolet ray, is irradiated for a predetermined time. In the exposure masks 70a, 70b, the mask pattern 72 serving as the conductive light-blocking film is formed in the position of the glass substrate 71 (FIG. 3) where the conductor pattern is supposed to be formed. Upon exposure, the portions of the dry films 80, 81 where the mask patterns 72 of the exposure masks 70a, 70b are absent are photocured, and the development process is conducted in this state.

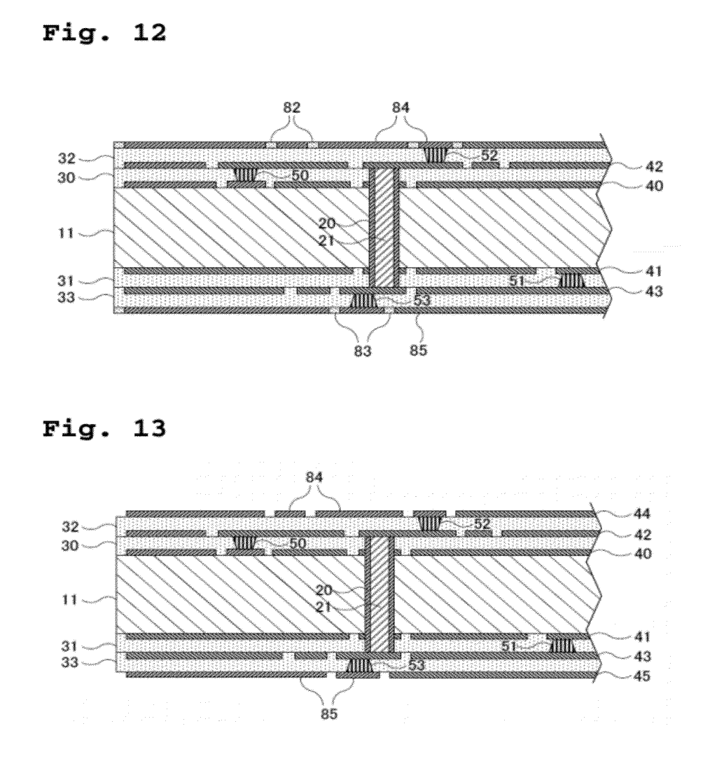

As shown in FIG. 11, after the development, the portions of the dry films 80, 81 directly under the mask pattern 72 are removed, and plating resists 82 and 83 are formed (plating-resist formation process). Subsequently, as shown in FIG. 12, the area where no plating resists 82, 83 is formed is subjected to electroless copper plating so that copper plating layers 84 and 85 corresponding to the mask pattern 72 are formed at the openings of the plating resists 82, 83 (plating process). At this time, the inside(s) of the via holes 52a, 53a (FIG. 10) serve as the via conductors 52, 53 in the copper plating layers 84, 85.

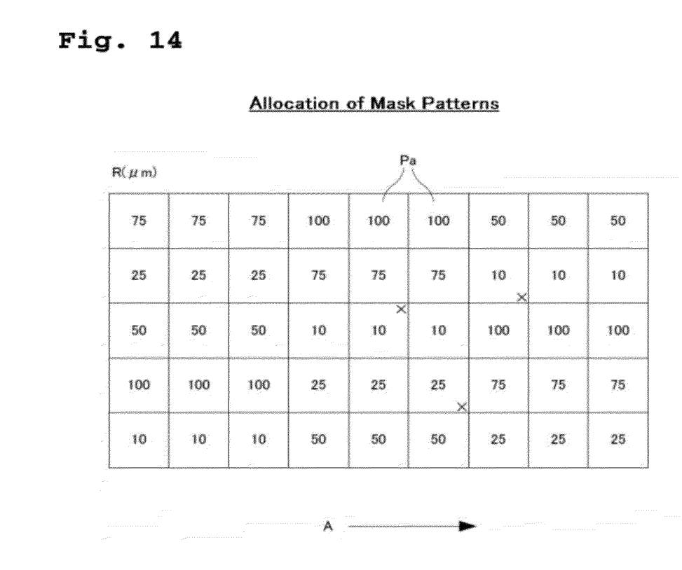

Next, as shown in FIG. 13, the plating resists 82, 83 are removed using a photoresist remover or the like (resist removal process) so as to form the conductor layers 44, 45 having the conductor patterns corresponding to the mask patterns 72 of the exposure masks 70a, 70b. Notably, in the conductor layers 44, 45, each surface of the copper plating layers 84, 85 and a portion of the copper thin layers where no copper plating layers 84, 85 are formed is etched by a predetermined depth (etching process). In this way, each surface of the copper plating layers 84, 85 are roughened, and the copper thin layer is removed so that the insulating layers 32, 33 situated underneath the copper thin layer are partially exposed.

Referring back now to FIG. 1, the film-like insulating resin material containing epoxy resin as a principal component is laminated on each of the conductor layers 44, 45 and cured to thereby form the insulating layers 34, 35. In a manner similar to that used to form the via conductors 50, 51, the via conductors 54, 55 are formed in the insulating layers 34, 35. Thereafter, copper plating layers are formed on each surface of the insulating layers 34, 35 through electroless copper plating so as to pattern the plurality of upper terminal pads 46 and the plurality of lower terminal pads 47 through, for example, a known subtractive process. Subsequently, photosensitive epoxy resin is applied to and cured on the upper surface of the insulating layer 34 and the lower surface of the insulating layer 35 so as to form the solder resist layers 36 and 37. Then, openings are patterned on both the upper and lower solder resist layers 36, 37. In this away, the wiring board 10 shown in FIG. 1 is completed.

Next, detailed evaluation results of the superior and unexpected advantages obtainable by using the method for manufacturing the wiring board 10 of the embodiment will be described. An accelerated test of electrostatic destruction was conducted using the exposure mask 70 corresponding to the intermediate product 60. The intermediate product 60 included a graphic pattern whose corners were formed into the chamfered portion Ra of FIG. 4. In the accelerated test, the exposure mask 70 was cleaned at predetermined times with a silicon roller for mask cleaning in a state that a neutralization of the silicon roller was switched off. Then, any pattern defect of the exposure mask 70 was observed. The exposure masks 70 in the test had product conductor patterns Pa that had a different radius of curvature R. The relationship between the influence of electrostatic destruction and the radius of curvature R of the graphic pattern was studied.

FIG. 14 is a schematic view of the mask pattern 72 arrangement of the exposure mask 70 used in the accelerated test. In FIG. 14, each rectangular graphic pattern corresponds to the product conductor pattern Pa. The product conductor pattern Pa was arranged in a 5×9 array, amounting to a total of 45 pieces. A numerical value shown on each product conductor pattern Pa shows the radius of curvature R of the chamfered portion Ra. That is, 180 corners (45×4) chamfered portions Ra existed on the 45 product conductor patterns Pa. In addition, four chamfered portions Ra in each product conductor pattern Pa had the same radius of curvature R. Five kinds of radius of curvatures R, i.e., R=10 micrometers, 25 micrometers, 50 micrometers, 75 micrometers and 100 micrometers, were adopted. In FIG. 14, there were 36 chamfered portions Ra for each kind of radius of curvature R, and the arrangement of the chamfered portions Ra was balanced to increase fair evaluation by accounting for positional variations. Then, the exposure mask 70 of FIG. 14 was cleaned using the silicon roller in direction A for 10 times, and any observed pattern defect caused by electrostatic destruction was indicated with an “x”.

The results of the accelerated test of electrostatic destruction show no pattern defect in the 36 chamfered portions Ra having R=50 micrometers, R=75 micrometers, and R=100 micrometers. However, two pattern defects out of 36 chamfered portions Ra were found for R=10 micrometers. Further, one pattern defect out of 36 chamfered portions Ra was found for R=25 micrometers. Thus, according to the results of the accelerated test, the radius of curvature R of each chamfered portion Ra of the mask pattern 72 is preferably at least R=50 micrometers or more.

Although the invention has been described with reference to the specific embodiments thereof, the invention is not limited to the above-described embodiments. Various modification and variation of the embodiments described above are possible without departing from the scope of the invention. For example, the above embodiment describes a case where the predetermined conductor layers formed by the exposure mask 70 in FIG. 3 are the conductor layers 44, 45 of the wiring board 10 in FIG. 1. However, all the conductor layers or only a single conductor layer may serve as the predetermined conductor layer(s). Further, although the wiring board 10 of the above embodiment has the wiring laminated body on each side of the core substrate 11, it may be formed on only one side of the core substrate 11. Alternatively, a wiring board without core substrate 11 may be adopted. Furthermore, although each graphic pattern of the exposure mask 70 assumes a rectangular form in the above embodiment, the shape of the graphic pattern may be any shape, except for a rectangle, as long as a corner thereof may be chamfered. In this case, the chamfered portion Ra of the graphic pattern is not limited to a rounded shape, but may be any shape, such as a combination of various curves and straight lines. Moreover, the structure of the wiring board 10 and the details of the manufacturing method thereof are not limited to the above-described embodiment, and any suitable modification that embodies the effects and advantages of the invention may be utilized.

### DESCRIPTION OF REFERENCE NUMERALS

10: Wiring board
11: Core substrate
20: Through hole conductor
21: Blockade body
30, 31, 32, 33, 34, 35: Insulating layer
34, 36: Solder resist layer
40, 41, 42, 43, 44, 45: Conductor layer
44, 46: Terminal pad
50, 51, 52, 53, 54, 55: Via conductor
60: intermediate product
61: Product formation area
61a: Unit area
62: Frame
70: Exposure Mask
71: Glass substrate
72: Mask pattern
Pa: Product conductor pattern
Pb: Frame conductor pattern
Ra: Chamfered portion
80, 81: Dry film
82, 83: Plating resist
84, 85: Copper plating layer

What is claimed is:

1. A method for manufacturing a wiring board including a wiring laminated body having an insulating layer and a conductor layer that are alternatively laminated, and the wiring board being formed by an intermediate product having a product formation area for a plurality of products, the method comprising:
forming a photosensitive resin layer on an insulating layer located underneath a predetermined conductor layer that is to be formed in the wiring laminated body;
forming a plating resist having an opening that corresponds to a mask pattern of an exposure mask by exposing and developing the photosensitive resin layer while the exposure mask is disposed on a surface of the photosensitive resin layer, the mask pattern having a conductive light-blocking film that blocks an exposure light irradiating to a conductor formation area of the predetermined conductor layer that is to be formed;
forming a metal plating layer that includes a conductor pattern corresponding to the mask pattern by applying a metal plating to the opening of the plating resist; and
removing the plating resist to form the predetermined conductor layer,
wherein each corner of a plurality of graphic patterns that constitute the conductive light-blocking film is chamfered by 50 micrometers or more.

2. The method for manufacturing a wiring board according to claim 1, wherein
the intermediate product further includes a frame surrounding the product formation area, and
the conductive light-blocking film further includes a pattern that blocks an exposure light irradiating to a conductor formation area of the frame.

3. The method for manufacturing a wiring board according to claim 2, wherein
the plurality of graphic patterns that constitute the conductive light-blocking film each correspond to one of the plurality of products in the product formation area.

4. The method for manufacturing a wiring board according to claim 1, wherein
each corner of the plurality of graphic patterns that constitute the conductive light-blocking film is chamfered in a circular arc shape with a radius of curvature of 50 micrometers or more.

5. The method for manufacturing a wiring board according to claim 1, further comprising:
forming a metallic thin layer on the surface of the insulating layer located underneath the predetermined conductor layer that is to be formed before the photosensitive resin layer formation step; and
etching a surface of the metal plating layer and a portion of the metallic thin layer where no metal plating layer is formed by a predetermined depth after removing the plating resist.

6. The method for manufacturing a wiring board according to claim 1,
wherein the predetermined conductor layer includes a solid conductor pattern electrically connected to a power supply or a ground potential.

7. The method for manufacturing a wiring board according to claim 1,
wherein the predetermined conductor layer is all of the conductor layers included in the wiring laminated body.
